(19) United States
(12) Patent Application Publication
(10) Pub. No.: US 2026/0190454 A1
(43) Pub. Date: Jul. 2, 2026

(54) SEMICONDUCTOR DEVICE

(71) Applicant: Industrial Technology Research Institute, Hsinchu (TW)

(72) Inventors: Chih-Hung Yen, Hsinchu County (TW); Hua-Mao Chen, Tainan City (TW)

(73) Assignee: Industrial Technology Research Institute, Hsinchu (TW)

(21) Appl. No.: 19/097,773

(22) Filed: Apr. 1, 2025

(30) Foreign Application Priority Data
Dec. 30, 2024 (TW) 113151431

(51) Int. Cl. H10D 84/00; H10D 30/01; H10D 30/65; H10D 62/10; H10D 62/60; H10D 62/80; H10D 62/83; H10D 62/832; H10D 62/852; H10D 64/01; H10D 64/66; H10D 64/68

(52) U.S. Cl. CPC H10D 84/212; H10D 30/0289; H10D 30/65; H10D 30/658; H10D 62/102; H10D 62/124; H10D 62/60; H10D 62/8303; H10D 62/8325; H10D 62/852; H10D 62/875; H10D 64/017; H10D 64/661; H10D 64/665; H10D 64/691; H10D 64/693

(57) ABSTRACT

A semiconductor device is provided. The semiconductor device includes a semiconductor substrate; a N type drift layer, a P-channel layer and a N+ layer sequentially stacked on the semiconductor substrate; a trench gate in the N+ layer, the P− channel layer and the N type drift layer; a P type ultra-wide bandgap epitaxial layer below the trench gate; and a gate insulating layer surrounding a bottom and a sidewall of the trench gate, and between the trench gate and the P type ultra-wide bandgap epitaxial layer.

### CROSS-REFERENCE TO RELATED APPLICATION

This application claims the priority benefit of Taiwan application serial no. 113151431, filed on Dec. 30, 2024. The entirety of the foregoing patent application is hereby incorporated by reference herein and made a part of this specification.

### TECHNICAL FIELD

The disclosure relates to a semiconductor device.

### BACKGROUND

In order to obtain higher-density unit cell spacing, the distance between the gate and the drain is increasingly reduced, which increases the capacitance between the gate and the drain (Cgd), thus the switching time of the device and the switching loss are reduced.

### SUMMARY

The disclosure provides a semiconductor device that may reduce the capacitance between the gate and the drain (Cgd).

The disclosure provides a semiconductor device. The semiconductor device includes: a semiconductor substrate; a N type drift layer, a P-channel layer and a N layer sequentially stacked on the semiconductor substrate; a trench gate in the N+ layer, the P− channel layer and the N type drift layer; a P type ultra-wide bandgap epitaxial layer below the trench gate; and a gate insulating layer surrounding a bottom and sidewall of the trench gate, and between the trench gate and the P type ultra-wide bandgap epitaxial layer.

The disclosure also provides a semiconductor device. The semiconductor device includes: a semiconductor substrate; a N type drift layer, a P− channel layer and a N+ layer sequentially stacked on the semiconductor substrate; a trench gate and a trench dummy gate in the N+ layer, the P− channel layer and the N type drift layer, wherein a thickness of the trench gate and a thickness of the trench dummy gate are different; a P type ultra-wide bandgap epitaxial layer below the trench gate and trench dummy gate; and a gate insulation layer surrounding a bottom of the trench gate, a sidewall of the trench gate, a bottom of the trench dummy gate, and a sidewall of the trench dummy gate, and between the trench gate and the P type ultra-wide bandgap epitaxial layer and between the trench dummy gate and the P type ultra-wide bandgap epitaxial layer.

The disclosure also provides a semiconductor device. The semiconductor device includes: a semiconductor substrate; a N type drift layer on the semiconductor substrate, wherein the N type drift layer comprises a middle region and two side regions, wherein a thickness of the middle region is thicker than a thickness of the two side regions; a bottom P type well epitaxial layer and a P type well on the two side regions of the N type drift layer, wherein the P type well is on the bottom P type well epitaxial layer; a gate and gate insulating layer on the middle region of the N type drift layer and on the P type well; and N layers in the P type well and on both sides of the gate.

In order to make the above-mentioned features and advantages of the disclosure more obvious and easy to understand, embodiments are given below and described in detail with reference to the accompanying drawings.

### BRIEF DESCRIPTION OF THE DRAWINGS

FIG. 1A to FIG. 1F are schematic cross-sectional views of a method for forming a semiconductor device according to the Embodiment 1 of the disclosure.

FIG. 2A to FIG. 2F are schematic cross-sectional views of a method for forming a semiconductor device according to the Embodiment 2 of the disclosure.

FIG. 3A to FIG. 3F are schematic cross-sectional views of a method for forming a semiconductor device according to the Embodiment 3 of the disclosure.

FIG. 4A to FIG. 4E are schematic cross-sectional views of a method for forming a semiconductor device according to the Embodiment 4 of the disclosure.

FIG. 5A and FIG. 5B are the dopant distribution diagrams of ion implantations and epitaxial processes.

### DESCRIPTION OF THE EMBODIMENTS

Embodiments are listed below and described in detail with reference to the accompanying drawings. The disclosure may be embodied in various forms and should not be limited to the embodiments described herein.

In addition, the drawings are for illustrative purposes only and are not drawn to original size. In addition, the same or similar symbols represent the same or similar elements, which will not be described one by one in the following paragraphs.

The terms “comprise”, “include”, “have”, etc., used in this description are all open terms, which means “including but not limited to”.

As used herein, “about,” “approximately” or “substantially” includes the recited value as well as the average within an acceptable range of deviations from the specific value that a person of ordinary skill in the art can determine, and the measure system limitations are also taken into account. For example, “about” may mean within one or more standard deviations of the stated value, or within ±30%, ±20%, ±10%, ±5%. Furthermore, the terms “approximately”, “approximately” or “substantially” used in this description may be used to select a more acceptable deviation range or standard deviation according to different properties or materials and other factors, and the same standard deviation does not need to be used for all properties or materials.

The terms used herein are only used to illustrate the embodiments and are not intended to limit the disclosure. Unless indicated by the context, the singular form includes the plural form.

### The Embodiment 1

1A to 1F are schematic cross-sectional views of a method for forming a semiconductor device according to the Embodiment 1 of the disclosure.

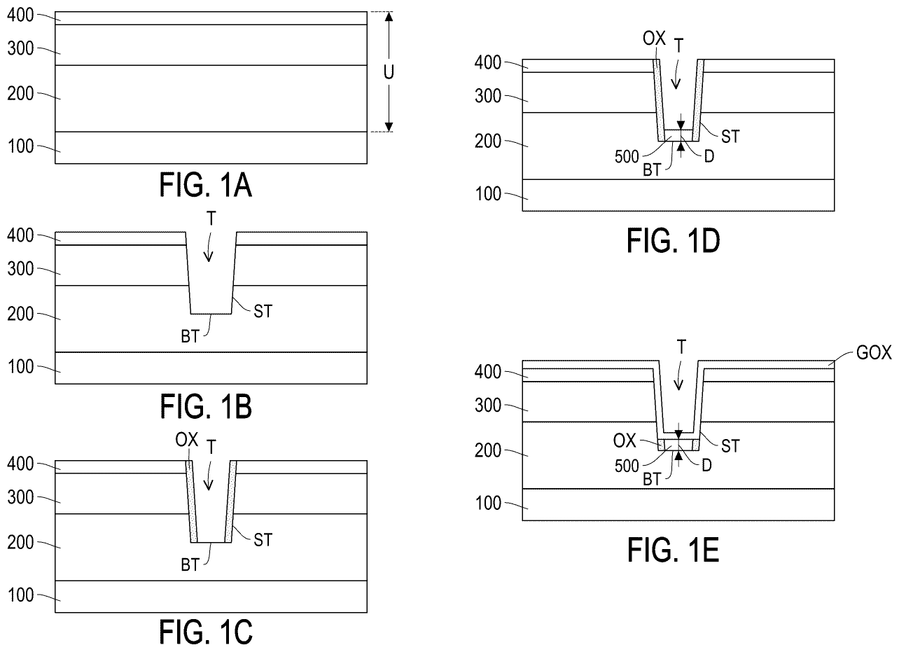

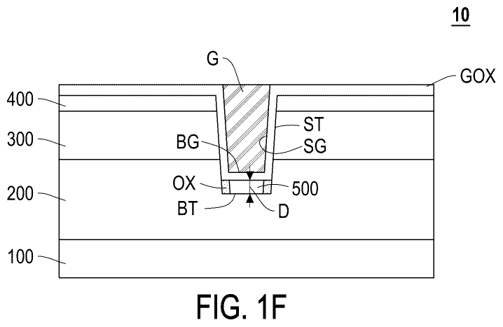

First, please refer to the semiconductor device 10 shown in FIG. 1F, which comprises a semiconductor substrate 100; a N type drift layer 200, a P− channel layer 300 and a N+ layer 400 sequentially stacked on the semiconductor substrate 100; a trench gate G in the N+ layer 400, the P− channel layer 300 and the N type drift layer 200; a P type ultra-wide bandgap epitaxial layer 500 below the trench gate G; and a gate insulating layer GOX surrounding a bottom BG and a sidewall SG of the trench gate G, and between the trench gate G and the P type ultra-wide bandgap epitaxial layer 500.

Please refer to FIGS. 1A to 1F for the method of forming the semiconductor device 10.

First, as shown in FIG. 1A, the N type drift layer 200, the P− channel layer 300 and the N+ layer 400 are formed in the upper portion U of the semiconductor substrate 100, wherein the P− channel layer 300 is on the N type drift layer 200, and the N+ layer 400 is on the P− channel layer 300.

In some embodiments, the semiconductor substrate 100 may include silicon carbide (SiC), silicon (Si), gallium nitride (GaN), β-gallium oxide (β-Ga₂O₃), aluminum nitride (AlN), diamond or sapphire, but not limited to those examples.

In some embodiments, the semiconductor substrate 100 may include a semiconductor substrate with dopants, for example, an N+ semiconductor substrate, but is not limited thereto.

In some embodiments, the ion implantation concentration and the ion implantation energy of the N type dopants and the P type dopants may be selected according to requirements for forming the N type drift layer 200, the P− channel layer 300 and the N+ layer 400 in the upper portion U of the semiconductor substrate 100, but are not limited thereto.

Next, as shown in FIG. 1B, the trench T are formed in the N+ layer 400, the P− channel layer 300 and the N type drift layer 200. The bottom BT of the trench T exposes the N type drift layer 200, and the sidewall ST of the trench T exposes the N+ layer 400, the P− channel layer 300 and the N type drift layer 200.

In some embodiments, the trench T may be formed by various methods of photolithography and etching. For example, the gallium nitride trench etching mainly adopts dry etching technology, such as reactive ion etching (RIE), induced coupling plasma (ICP) etching, or high density plasma (HPD) etching.

Next, as shown in FIG. 1C, an oxide layer OX is formed on the sidewall ST of the trench T.

In some embodiments, the above-mentioned oxide layer OX may be formed in the following manner, but is not limited thereto: first, comprehensively depositing an oxide hard mask (not shown) on the N+ layer 400 and inside the trench T; then etching back is performed to remove the oxide layer hard mask on the N+ layer 400 and the bottom BT of the trench T, so as to expose the N+ layer 400 and the bottom BT of the trench T, leaving only the oxide layer OX on the sidewall ST of the trench T.

Next, please refer to FIG. 1D, the P type ultra-wide bandgap epitaxial layer 500 is formed on the bottom BT of the trench T using an epitaxial process. The oxide layer OX is between the sidewall of the P type ultra-wide bandgap epitaxial layer 500 and the N type drift layer 200.

In some embodiments, the P type ultra-wide bandgap epitaxial layer 500 may be formed by the metal organic chemical vapor deposition (MOCVD) or the molecular beam epitaxy (MBE) technology.

In some embodiments, the P type ultra-wide bandgap epitaxial layer 500 may include 4H-silicon carbide (4H—SiC), gallium nitride (GaN), β-gallium oxide (β-Ga₂O₃), aluminum gallium nitride (AlGaN), aluminum nitride (AlN) or germanium dioxide (GeO₂), but are not limited to those examples.

In some embodiments, the bandgap of the P type ultra-wide bandgap epitaxial layer 500 ranges from about 3.2 eV to 6.0 eV.

In some embodiments, the depth D of the P type ultra-wide bandgap epitaxial layer 500 is more than 0.1 mm and less than 1 mm, and is completely located in the N type drift layer 200.

In some embodiments, the P-type dopant concentration of the P type ultra-wide bandgap epitaxial layer 500 is more than 1×10¹⁷ (cm⁻³) and less than 5×10¹⁹ (cm⁻³).

Next, please refer to FIG. 1E. First, the exposed oxide layer OX on the sidewall ST of the trench T is removed. Then the gate oxide layer GOX is formed on the P type ultra-wide bandgap epitaxial layer 500, the sidewall ST of the trench T and the N+ layer 400.

In some embodiments, the above-mentioned gate oxide layer GOX may be formed on the P type ultra-wide bandgap epitaxial layer 500, the sidewall ST of the trench T and the N+ layer 400 by various deposition methods.

In some embodiments, the gate oxide layer GOX may include SiO₂, SiON, SiN or high dielectric constant materials, but is not limited thereto. The high dielectric constant material may include Al₂O₃, HfO₂ or ZrO₂, but is not limited thereto.

Next, please refer to FIG. 1F. The gate material is filled in the trench T to form a trench gate G.

In some embodiments, the filling gate material may include poly-Si, titanium (Ti), aluminum (Al), tungsten (W) or gold (Au) to form a trench polycrystalline silicon gate or trench metal gate, but not limited to those examples. It may be a general gate or a dummy gate depending the requirements.

In the above-mentioned semiconductor device 10, the technical feature of the P type ultra-wide bandgap epitaxial layer 500 located under the trench gate G is used to form a PN interface with the N type drift layer 200, so that the gate insulating layer GOX capacitor is connected in series with the PN interface capacitance, the capacitance between the gate and the drain (Cgd) thus is reduced.

The self-aligned P type ultra-wide bandgap epitaxial layer 500 located under the trench gate G may also reduce the bottom electric field while avoiding the ion implantation diffusion that causes the JFET area to be pinched, thus the on-resistance is effectively reduced.

Moreover, the above-mentioned heterojunction may reduce the transmission of holes, and the probability of avalanche collapse may be reduced, thereby the collapse voltage may be increased.

### The Embodiment 2

The semiconductor device 20 of the Embodiment 2 and the forming method thereof are generally similar to the semiconductor device 10 of the Embodiment 1 and the forming method thereof. The only difference lies only in that, the semiconductor device 20 of the Embodiment 2 the exposed oxide layer OX on the sidewall ST of the trench T is not removed after forming the P type ultra-wide bandgap epitaxial layer 500, as shown in FIG. 1D. Instead, a gate oxide layer GOX is directly formed thereon and above the P type ultra-wide bandgap epitaxial layer 500 and the N+ layer 400, as shown in FIG. 1E.

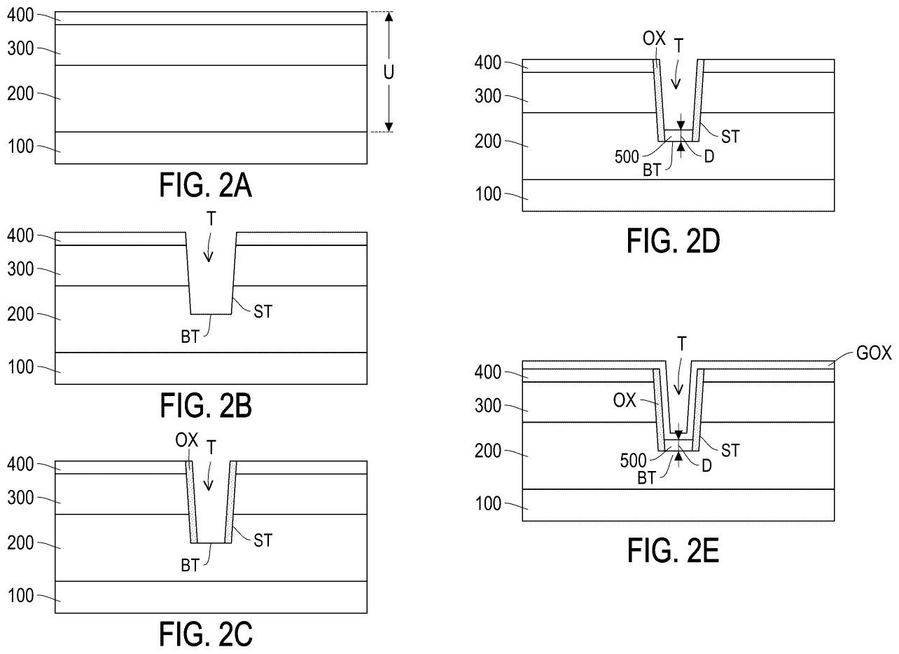

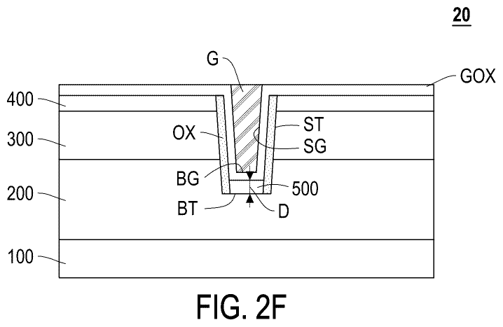

Next, as shown in FIG. 1F and related descriptions of Embodiment 1, the gate material is filled in the trench T in FIG. 2E to form a trench gate G, as shown in FIG. 2F.

### The Embodiment 3

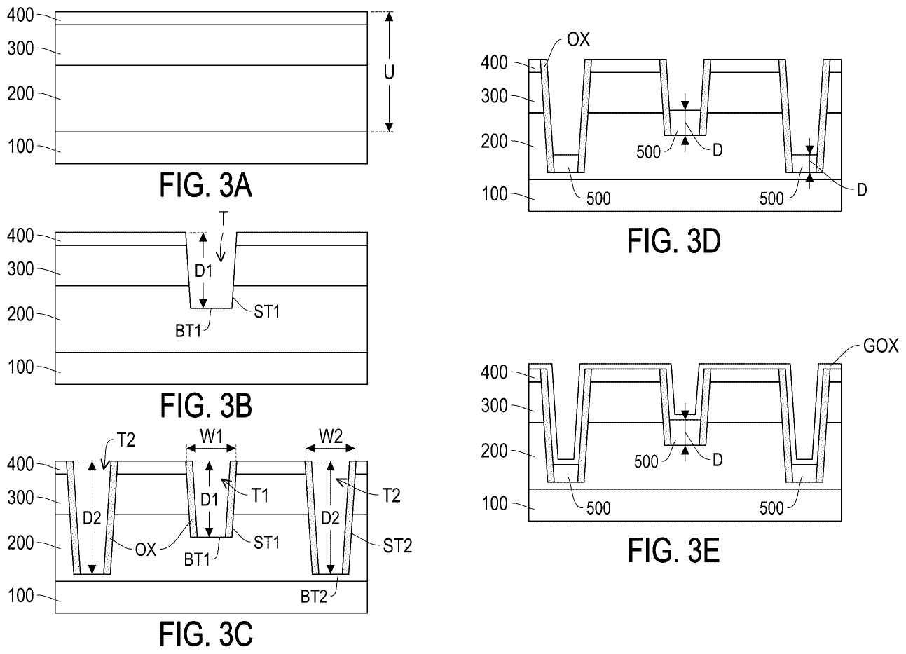

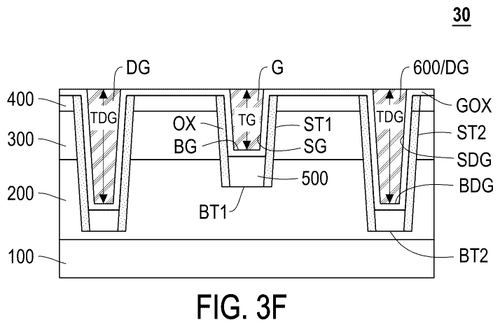

The semiconductor device 30 of the Embodiment 3 and the forming method thereof are generally similar to the semiconductor device 10 of the Embodiment 1 and the forming method thereof. The only difference is that in addition to the trench gate G, the semiconductor device 30 of the Embodiment 3 also includes the trench dummy gate DG with different depth, as shown in FIG. 3C.

FIG. 3A to FIG. 3F are schematic cross-sectional views of a method for forming a semiconductor device according to the Embodiment 3 of the disclosure.

First, please refer to the semiconductor device 30 shown in FIG. 3F, which comprises a semiconductor substrate 100; a N type drift layer 200, a P− channel layer 300 and a N+ layer 400 sequentially stacked on the semiconductor substrate 100; a trench gate G and a trench dummy gate DG in the N+ layer 400, the P− channel layer 300 and the N type drift layer 200, a thickness TG of the trench gate G and a thickness TDG of the trench dummy gate DG are different; a P type ultra-wide bandgap epitaxial layer 500 below the trench gate G and the trench dummy gate DG; and a gate insulating layer GOX, surrounding a bottom BG of the trench gate G, a sidewall SG of the trench gate G, a bottom BDG of the trench dummy gate DG, and a sidewall SDG of the trench dummy gate DG, and is between the trench gate G and the P type ultra-wide bandgap epitaxial layer 500 and between the trench dummy gate DG and the P type ultra-wide bandgap epitaxial layer 500.

Please refer to FIG. 3A to FIG. 3F for the method of forming the semiconductor device 30.

First, as shown in FIG. 3A, the N type drift layer 200, the P− channel layer 300 and the N+ layer 400 are formed in the upper portion U of the semiconductor substrate 100, wherein the P− channel layer 300 is on the N type drift layer 200, and the N+ layer 400 is on the P− channel layer 300.

In some embodiments, the semiconductor substrate 100 may include silicon carbide (SiC), silicon (Si), gallium nitride (GaN), β-gallium oxide (β-Ga₂O₃), aluminum nitride (AlN), diamond or sapphire, but not limited to those examples.

In some embodiments, the semiconductor substrate 100 may include a semiconductor substrate with dopants, for example, an N+ semiconductor substrate, but is not limited thereto.

In some embodiments, the ion implantation concentration and the ion implantation energy of the N type dopants and the P type dopants may be selected according to requirements for forming the N type drift layer 200, the P− channel layer 300 and the N+ layer 400 in the upper portion U of the semiconductor substrate 100, but are not limited thereto.

Next, please refer to FIG. 3C in advance. The first trench T1 and the second trench T2 are formed in the N+ layer 400, the P− channel layer 300 and the N type drift layer 200, wherein the depth D1 of the first trench T1 is different from the depth D2 of the second trench T2.

In some embodiments, the depth D2 of the second trench T2 may be deeper than the depth D1 of the first trench T1, as shown in FIG. 3C, but is not limited thereto. For example, a third trench (not shown) may be further included, the depth of the third trench may be shallower than the depth D1 of the first trench T1, may be between the depth D1 of the first trench T1 and the depth D2 of the second trench T2, or may be deeper than the depth D2 of the second trench T2. Furthermore, trenches with various depths, such as the fourth trench (not shown), the fifth trench (not shown) and etc. may be included according to device design requirements.

As shown in FIG. 3C, when the depth D1 of the first trench T1 is shallower than the depth D2 of the second trench T2, the electric field at the bottom of the first trench T1 will be lower than the electric field at the bottom of the second trench T2. Therefore, the thickness D or concentration of the P type ultra-wide bandgap epitaxial layer 500 in the first trench T1 needs to be lower than the thickness D or concentration of the P type ultra-wide bandgap epitaxial layer 500 in the second trench T2. On the contrary, if the depth of the first trench is deeper than the depth of the second trench, the thickness or concentration of the P type ultra-wide bandgap epitaxial layer of the first trench needs to be higher than the P-type ultra-wide gap epitaxial layer of the second trench. The thickness of the bandgap epitaxial layer.

In some embodiments, the width W1 of the first trench T1 and the width W2 of the second trench T2 may be different or the same.

In addition, the first trench T1 may be formed one or more, and the second trench T2 may be formed one or more. As shown in FIG. 3C, it includes one first trench T1 and two second trenches T2, but the actual application is not limited thereto. This figure is only for the illustration and is not intended to limit the disclosure.

In some embodiments, the first trench T1 may be formed first, and then the second trench T2 may be formed, as shown in FIGS. 3B to 3C, but the formation order is not limited to this. It could be also that the second trench T2 is formed first, then the second trench T2 is formed. Or the first trench T1 and the second trench T2 may also formed simultaneously.

In some embodiments, the first trench T1 and the second trench T2 may be formed by various methods of photolithography and etching. For example, the gallium nitride trench etching mainly adopts dry etching technology, such as reactive ion etching (RIE), inductive couple plasma (ICP) etching or high density plasma (HPD) etching.

The following embodiment is to form the first trench T1 first, and then form the second trench T2 as an example. As shown in FIG. 3B, the first trench T1 is formed in the N+ layer 400, the P− channel layer 300 and the N type drift layer 200. The bottom BT1 of the first trench T1 exposes the N type drift layer 200, and the sidewall ST1 of the first trench T1 exposes the N+ layer 400, the P− channel layer 300 and the N type drift layer 200.

Then, as shown in FIG. 3C, a second trench T2 is formed in the N+ layer 400, the P− channel layer 300 and the N type drift layer 200. The bottom BT2 of the second trench T2 exposes the N type drift layer 200, and the sidewall ST2 of the second trench T2 exposes the N+ layer 400, the P− channel layer 300 and the N type drift layer 200.

Then, as shown in FIG. 3C, an oxide layer OX is formed on the sidewall ST1 of the first trench T1 and the sidewall ST2 of the second trench T2.

In some embodiments, the above-mentioned oxide layer OX may be formed in the following manner, but is not limited thereto: first, comprehensively depositing an oxide hard mask (not shown) on the N+ layer 400, and inside the first trench T1 and the second trench T2; then etching back is performed to remove the oxide hard mask on the N+ layer 400, the bottom BT1 of the first trench T1 and the bottom BT2 of the second trench T2, so as to expose the N+ layer 400, the he bottom BT1 of the trench T1 and the bottom BT2 of the second trench T2, leaving only the oxide layer OX on the sidewall ST1 of the first trench T1 and the sidewall ST2 of the second trench T2.

Next, please refer to FIG. 3D, a P type ultra-wide bandgap epitaxial layer 500 is formed on the bottom BT1 of the first trench T1 and the bottom BT2 of the second trench T2 using an epitaxial process. The oxide layer OX is between the sidewall of the P type ultra-wide bandgap epitaxial layer 500 and the N type drift layer 200.

In some embodiments, the P type ultra-wide bandgap epitaxial layer 500 may be formed by the metal organic chemical vapor deposition (MOCVD) or the molecular beam epitaxy (MBE) technology.

In some embodiments, the P type ultra-wide bandgap epitaxial layer 500 may include 4H-silicon carbide (4H—SiC), gallium nitride (GaN), β-gallium oxide (β-Ga₂O₃), aluminum gallium nitride (AlGaN), aluminum nitride (AlN) or germanium dioxide (GeO₂), but are not limited to those examples.

In some embodiments, the bandgap of the P type ultra-wide bandgap epitaxial layer 500 ranges from about 3.2 eV to 6.0 eV.

Since the depth D1 and width W1 of the first trench T1 and the depth D2 and width W2 of the second trench T2 are not exactly the same, the depth D of the formed P type ultra-wide bandgap epitaxial layer 500 may be different. For example, as shown in FIG. 3D, when the width W1 of the first trench T1 is the same as the width W2 of the second trench T2, the depth D of P-type ultra-wide energy in the first trench T1 with a shallower depth D1 is thicker than the depth D of the P type ultra-wide bandgap epitaxial layer 500 in the second trench T2 with a deeper depth D2. So the depth of the P type ultra-wide bandgap epitaxial layer 500 may be adjusted by adjusting the width and the depth of the trenches.

In some embodiments, the depth D of the P type ultra-wide bandgap epitaxial layer 500 is more than 0.1 mm and less than 1 mm, and is completely located in the N type drift layer 200.

In some embodiments, the P-type dopant concentration of the P type ultra-wide bandgap epitaxial layer 500 is more than 1×10¹⁷ (cm⁻³) and less than 5×10¹⁹ (cm⁻³).

Next, please refer to FIG. 3E. First, the exposed oxide layer OX on the sidewall ST1 of the first trench T1 and the sidewall ST2 of the second trench T2 is removed. Then the gate oxide layer GOX is formed on the P type ultra-wide bandgap epitaxial layer 500, the sidewall ST1 of the first trench T1, the sidewall ST2 of the second trench T2 and the N+ layer 400.

In some embodiments, the above-mentioned gate oxide layer GOX may be formed on the P type ultra-wide bandgap epitaxial layer 500, the sidewall ST1 of the first trench T1, the sidewall ST2 of the second trench T2 and the N+ layer 400 by various deposition methods.

In some embodiments, the gate oxide layer GOX may include SiO₂, SiON, SiN or high dielectric constant materials, but is not limited thereto. The high dielectric constant material may include Al₂O₃, HfO₂ or ZrO₂, but is not limited thereto.

Next, please refer to FIG. 3F. The gate material is filled in the first trench T1 and the second trench T2 to form a trench gate G and a trench dummy gate DG respectively.

In some embodiments, the filling gate material may include poly-Si, titanium (Ti), aluminum (Al), tungsten (W) or gold (Au) to form a trench polycrystalline silicon gate, a trench metal gate, a trench polycrystalline silicon dummy gate, a trench metal dummy gate, but not limited to those examples.

In the above-mentioned semiconductor device 30, the technical feature of the P type ultra-wide bandgap epitaxial layer 500 located under the trench gate G and the trench dummy gate DG is used to form a PN interface with the N type drift layer 200, so that the gate insulating layer GOX capacitor is connected in series with the PN interface capacitor, thus the capacitance between the gate and drain (Cgd) is reduced.

The self-aligned P type ultra-wide bandgap epitaxial layer 500 located under the trench gate G and the trench dummy gate DG may also reduce the bottom electric field while avoiding the ion implantation diffusion that causes the JFET area to be pinched, thus the on-resistance is effectively reduced.

Moreover, the above-mentioned heterojunction may reduce the transmission of holes, and the probability of avalanche collapse may be reduced, thereby the collapse voltage may be increased.

### The Embodiment 4

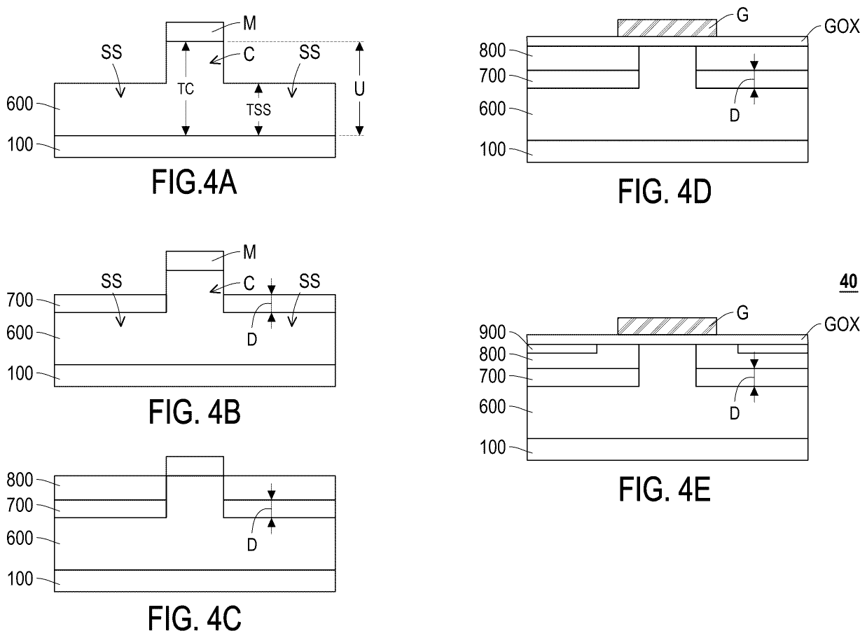

FIG. 4A to FIG. 4E are schematic cross-sectional views of a method for forming a semiconductor device according to the Embodiment 4 of the disclosure.

First, please refer to the semiconductor device 40 shown in FIG. 4E, which comprises a semiconductor substrate 100; a N type drift layer 600 on the semiconductor substrate 100, the N type drift layer 600 comprises a middle region C and two side regions SS, a thickness TC of the middle region C is thicker than a thickness TSS of the two side regions SS; a bottom P well epitaxial layer 700 and the P type well 800 on the two sides SS of the N type drift layer 600, the P type well 800 is on the bottom P well epitaxial layer 700; a gate G and a gate insulation layer GOX on the middle region C of the N type drift layer 600 and the P type well 800; and a N+ layer 900 in the P type well 800 and on both sides of the gate G.

Please refer to FIG. 4A to FIG. 4E for the method of forming the semiconductor device 40.

First, after growing crystals on the semiconductor substrate 100, for example, techniques such as metal organic chemical vapor deposition (MOCVD) or molecular beam epitaxy (MBE) may be used to grow the N type drift layer 600 on the semiconductor substrate 100, a hard mask M is grown on the N type drift layer 600 by the plasma-assisted chemical vapor deposition, for example. The material of the hard mask M may be, for example, SiO₂ or SiN, but is not limited thereto. Then, as shown in FIG. 4A, a portion of the N type drift layer 600 that is not covered by the hard mask M is removed, so that N type drift layer 600 including a middle region C and two side regions SS on the semiconductor substrate 100 is formed, wherein the thickness TC of the middle region C of the N type drift layer 600 is thicker than the thickness TSS of the two side regions SS of the N type drift layer 600.

In some embodiments, the semiconductor substrate 100 may include silicon carbide (SiC), silicon (Si), gallium nitride (GaN), β-gallium oxide (β-Ga₂O₃), aluminum nitride (AlN), diamond or sapphire, but not limited to those examples.

In some embodiments, the semiconductor substrate 100 may include a semiconductor substrate with dopants, for example, an N+ semiconductor substrate, but is not limited thereto.

In some embodiments, the upper portion U of the semiconductor substrate 100 may be doped with N-type by ion implantation, for example. Then the hard mask M, as shown in FIG. 4A, may be used with photolithography and etching to form the N type drift layer 600 of the thickness TC of the middle region C thicker than the thickness TSS of the two side regions SS.

Next, as shown in FIG. 4B, a first epitaxial process is used to form a bottom P well epitaxial layer 700 on both sides SS of the N type drift layer 600.

In some embodiments, the bottom P well epitaxial layer 700 may be formed by Metal organic chemical vapor deposition (MOCVD) or molecular beam epitaxy (MBE).

In some embodiments, the bottom P well epitaxial layer 700 may include 4H-silicon carbide (4H—SiC), gallium nitride (GaN), β-gallium oxide (β-Ga₂O₃), aluminum gallium nitride (AlGaN), Aluminum nitride (AlN) or germanium dioxide (GeO₂), but not limited to those examples.

In some embodiments, the bandgap of the bottom P well epitaxial layer 700 ranges from about 3.2 eV to about 6.0 eV.

In some embodiments, the depth D of the bottom P well epitaxial layer 700 is more than 0.1 mm and less than 1 mm.

In some embodiments, the concentration of the P-type dopants of the bottom P well epitaxial layer 700 is more than 1×10¹⁷ (cm⁻³) and less than 5×10¹⁹ (cm⁻³).

Next, as shown in FIG. 4C, a second epitaxial process is used to form a P type well 800 on the bottom P well epitaxial layer 700.

Then, the hard mask M is removed, and an N+ layer 900 is formed in the P type well 800 by ion implantation, as shown in FIG. 4D.

Next, please refer to FIG. 4D, and then the definition process of the gate insulating layer GOX and the gate G is subsequent preformed.

As shown in FIG. 4E, a gate insulating layer GOX is formed on the N type drift layer 600, the P type well 800 and the N+ layer 900.

In some embodiments, the gate oxide layer GOX may be formed on the middle region C of the N type drift layer 600, the P type well 800 and the N+ layer 900 by various deposition methods.

In some embodiments, the gate oxide layer GOX may include SiO₂, SiON, SiN or high dielectric constant materials, but is not limited thereto. The high dielectric constant material may include Al₂O₃, HfO₂ or ZrO₂, but is not limited thereto.

Then, by methods of photolithography and etching, the gate G is defined on the gate insulating layer GOX, and the gate G is on the middle region C of the N type drift layer 600 and the two side regions SS of the portion adjacent to the middle region C. as shown in FIG. 4D.

In some embodiments, the gate G may be formed of polycrystalline silicon (poly-Si), titanium (Ti), aluminum (Al), tungsten (W) or gold (Au) to form a general gate or a dummy gate.

In the above-mentioned semiconductor device 40, the technical feature that the bottom P well epitaxial layer 700 forms a PN interface with the N type drift layer 600 is utilized, so that the capacitance of the gate insulating layer GOX is connected in series with the PN interface capacitance, the capacitance between the gate and the drain (Cgd) thus is reduced.

The self-aligned bottom P well epitaxial layer 700 may also reduce the bottom electric field while avoiding the ion implantation diffusion that causes the JFET area to be pinched, thus the on-resistance is effectively reduced.

Moreover, the above-mentioned heterojunction may reduce the transmission of holes, and the probability of avalanche collapse may be reduced, thereby the collapse voltage may be increased.

Traditionally, when using P well implantation technology, the P well area is formed at the bottom of the device. However, due to the collision effect of ion implantation and the high-temperature annealing process, the P-well area tends to spread to both sides, causing its actual width to be larger than originally designed. Such a diffusion phenomenon will cause a pinch effect in the channel between the P well area and the bottom P Well (BPW) area, thereby increasing the on-resistance of the device by more than 70% and adversely affecting the performance of the device.

In contrast, using epitaxial growth technology to form the P well region can effectively avoid these problems. Since epitaxial technology does not rely on high-temperature annealing, it can more accurately control the thickness and width of the P well area, reduce unnecessary lateral diffusion, and thereby stabilize the on-resistance of the device. This method can not only improve the accuracy of the manufacturing process, but also improve the performance and stability of the device, reducing changes in low conduction current.

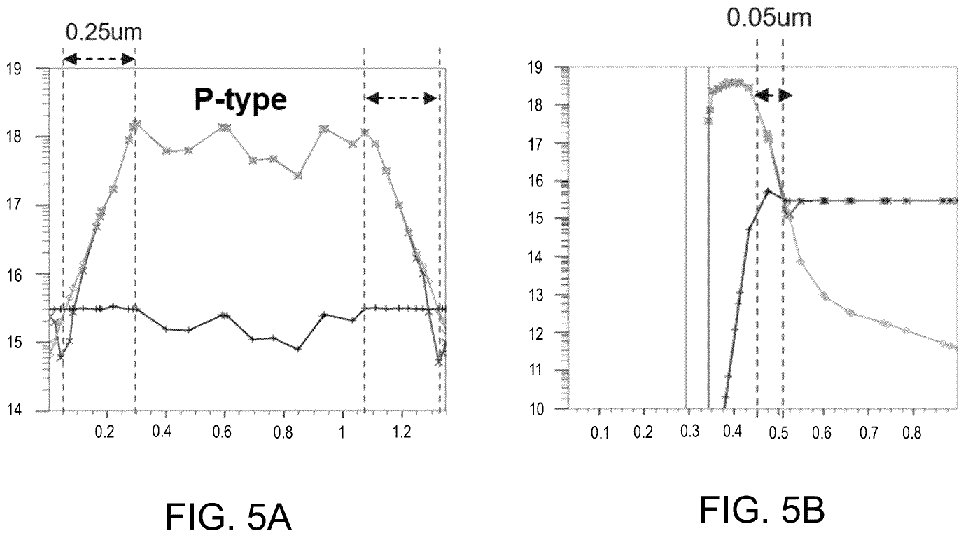

Please refer to FIG. 5A and FIG. 5B, which are dopant distribution diagrams using ion implantation and epitaxial processes respectively. As shown in FIG. 5A, the P type dopants using the ion implantation is laterally diffused in the material layer up to about 0.25 μm. However, as shown in FIG. 5B, the P type dopants using the epitaxial process is laterally diffused only about 0.05 μm in the material layer. Therefore, the P type dopants using the epitaxial process can minimize the diffusion behavior in the material layer compared to the P type dopants using the ion implantation. Therefore, the epitaxial process can more accurately control the boundaries of P type dopants, and its distribution is more concentrated than that of P type dopants using ion implantation to effectively block the electric field and increase the breakdown voltage.

Moreover, from the microscopic point of view, even if the influence of high-temperature annealing is not considered, the dopants of the doped epitaxial layer formed by the epitaxial process are evenly distributed inside the epitaxial layer, which is a non-Gaussian distribution. But the dopants in the ion implantation layer are a non-uniform distribution of Gaussian distribution. Therefore, the epitaxial layer also has higher uniformity than the ion implantation layer.

In addition, by using P type wider bandgap materials for heteroepitaxy, the band discontinuity of the heterojunction helps to inject carriers more effectively under the action of the electric field. And the electrons and the holes according are separated according to the characteristics of different materials. For example, in a heterojunction, the electrons may be more concentrated in a conductive material, while the holes remain in another material, which may improve the transport behavior of the carriers.

Furthermore, the difference in bandgap structure between heterojunction materials may produce bandgap discontinuities, which may effectively control the electric field distribution and reduce the occurrence of the high electric field concentration points (i.e. hot spots), thus the leakage current inside the device may be reduced.

Based on the above, the disclosure provides a semiconductor device and a method of forming the same, by the technical characteristics of forming a PN interface through a P type ultra-wide bandgap epitaxial layer and an N type drift layer, or technical characteristics of a bottom P type well epitaxial layer and an N type drift layer, the capacitance between the gate and the drain (Cgd) after connecting the P-N interface capacitor in series is reduced. At the same time, the presence of the P type ultra-wide bandgap epitaxial layer and the N type drift layer or the bottom P type well epitaxial layer and the N type drift layer may also avoid pinching the JFET area due to ion implantation diffusion, thereby the conduction resistance is effectively reduced. In addition, the heterojunction may reduce the transmission of the holes and reduce the probability of avalanche collapse, thereby increasing the collapse voltage.

Although the disclosure has been disclosed above through embodiments, they are not intended to limit the disclosure. Any person with ordinary knowledge in the relevant technical field may make some modifications and modifications without departing from the spirit and scope of the disclosure. Therefore, the protection scope of the disclosure shall be determined by the appended patent application scope.

What is claimed is:

1. A semiconductor device, comprising:
a semiconductor substrate;
a N type drift layer, a P− channel layer and a N+ layer sequentially stacked on the semiconductor substrate;
a trench gate in the N+ layer, the P− channel layer and the N type drift layer;
a P type ultra-wide bandgap epitaxial layer below the trench gate; and
a gate insulating layer surrounding a bottom and a sidewall of the trench gate, and between the trench gate and the P type ultra-wide bandgap epitaxial layer.

2. The semiconductor device according to claim 1, wherein the semiconductor substrate comprises silicon carbide (SiC), silicon (Si), gallium nitride (GaN), β-gallium oxide (β-Ga₂O₃), aluminum nitride (AlN), diamond or sapphire.

3. The semiconductor device according to claim 1, wherein the semiconductor substrate comprises a doped semiconductor substrate.

4. The semiconductor device according to claim 1, wherein the semiconductor substrate comprises a N+ semiconductor substrate.

5. The semiconductor device according to claim 1, the P type ultra-wide bandgap epitaxial layer comprises 4H-silicon carbide (4H—SiC), gallium nitride (GaN), β-gallium oxide (β-Ga₂O₃), aluminum gallium nitride (AlGaN), nitride Aluminum (AlN) or germanium dioxide (GeO₂).

6. The semiconductor device according to claim 1, wherein an bandgap range of the P type ultra-wide bandgap epitaxial layer is from 3.2 eV to 6.0 eV.

7. The semiconductor device according to claim 1, wherein a depth of the P type ultra-wide bandgap epitaxial layer is greater than 0.1 mm and less than 1 mm.

8. The semiconductor device according to claim 1, wherein a concentration of P type dopants in the P type ultra-wide bandgap epitaxial layer is more than 1×10¹⁷ (cm⁻³) and less than 5×10¹⁹ (cm⁻³).

9. The semiconductor device according to claim 1, wherein the gate insulating layer comprises SiO₂, SiON, SiN or a high dielectric constant material.

10. The semiconductor device according to claim 9, wherein the high dielectric constant material comprises Al₂O₃, HfO₂ or ZrO₂.

11. The semiconductor device according to claim 1, wherein the trench gate comprises polycrystalline silicon (poly-Si), titanium (Ti), aluminum (Al), tungsten (W) or gold (Au).

12. The semiconductor device according to claim 1, wherein the trench gate is a general gate or a dummy gate.

13. The semiconductor device according to claim 1, further comprising an oxide layer between a sidewall of the P type ultra-wide bandgap epitaxial layer and the N type drift layer.

14. A semiconductor device, comprising:
a semiconductor substrate;
a N type drift layer, a P− channel layer and a N+ layer sequentially stacked on the semiconductor substrate;
a trench gate and a trench dummy gate in the N+ layer, the P− channel layer and the N type drift layer, wherein a thickness of the trench gate and a thickness of the trench dummy gate are different;
a P type ultra-wide bandgap epitaxial layer below the trench gate and the trench dummy gate; and
a gate insulation layer surrounding a bottom of the trench gate, a sidewall of the trench gate, a bottom of the trench dummy gate, and a sidewall of the trench dummy gate, and between the trench gate and the P type ultra-wide bandgap epitaxial layer and between the trench dummy gate and the P type ultra-wide bandgap epitaxial layer.

15. The semiconductor device according to claim 14, wherein the semiconductor substrate comprises silicon carbide (SiC), silicon (Si), gallium nitride (GaN), β-gallium oxide (β-Ga₂O₃), aluminum nitride (AlN), diamond or sapphire.

16. The semiconductor device according to claim 14, wherein the semiconductor substrate comprises a doped semiconductor substrate.

17. The semiconductor device according to claim 14, wherein the semiconductor substrate comprises a N+ semiconductor substrate.

18. The semiconductor device according to claim 14, the P type ultra-wide bandgap epitaxial layer comprises 4H-silicon carbide (4H—SiC), gallium nitride (GaN), β-gallium oxide (β-Ga₂O₃), aluminum gallium nitride (AlGaN), nitride Aluminum (AlN) or germanium dioxide (GeO₂).

19. The semiconductor device according to claim 14, wherein an bandgap range of the P type ultra-wide bandgap epitaxial layer is from 3.2 eV˜6.0 eV.

20. The semiconductor device according to claim 14, wherein a depth of the P type ultra-wide bandgap epitaxial layer is greater than 0.1 mm and less than 1 mm.

21. The semiconductor device according to claim 14, wherein a concentration of P type dopants of the P type ultra-wide bandgap epitaxial layer is more than 1×10¹⁷ (cm⁻³) and less than 5×10¹⁹ (cm⁻³).

22. The semiconductor device according to claim 14, wherein the gate insulating layer comprises SiO₂, SiON, SiN or a high dielectric constant material.

23. The semiconductor device according to claim 22, wherein the high dielectric constant material comprises Al₂O₃, HfO₂ or ZrO₂.

24. The semiconductor device according to claim 14, wherein the trench gate comprises polycrystalline silicon (poly-Si), titanium (Ti), aluminum (Al), tungsten (W) or gold (Au).

25. The semiconductor device according to claim 14, wherein the trench dummy gate comprises polycrystalline silicon (poly-Si), titanium (Ti), aluminum (Al), tungsten (W) or gold (Au).

26. The semiconductor device according to claim 14, further comprising an oxide layer between sidewall of the P type ultra-wide bandgap epitaxial layer and the N type drift layer.

27. A semiconductor device, comprising:
a semiconductor substrate;
a N type drift layer on the semiconductor substrate, wherein the N type drift layer comprises a middle region and two side regions, wherein a thickness of the middle region is thicker than a thickness of the two side regions;
a bottom P type well epitaxial layer and a P type well on the two side regions of the N type drift layer, wherein the P type well is on the bottom P type well epitaxial layer;
a gate and a gate insulating layer on the middle region of the N type drift layer and on the P type well; and
N+ layers in the P type well and on both sides of the gate.

28. The semiconductor device according to claim 27, the semiconductor substrate comprises silicon carbide (SiC), silicon (Si), gallium nitride (GaN), β-gallium oxide (β-Ga₂O₃), aluminum nitride (AlN), diamond or sapphire.

29. The semiconductor device according to claim 27, wherein the semiconductor substrate comprises a doped semiconductor substrate.

30. The semiconductor device according to claim 27, wherein the semiconductor substrate comprises N+ semiconductor substrate.

31. The semiconductor device according to claim 27, the bottom P type well epitaxial layer comprises 4H-silicon carbide (4H—SiC), gallium nitride (GaN), β-gallium oxide (β-Ga₂O₃), aluminum gallium nitride (AlGaN), aluminum nitride (AlN) or germanium dioxide (GeO₂).

32. The semiconductor device according to claim 27, wherein a bandgap range of the bottom P well epitaxial layer is from 3.2 eV˜6.0 eV.

33. The semiconductor device according to claim 27, wherein the depth of the bottom P well epitaxial layer is greater than 0.1 mm and less than 1 mm.

34. The semiconductor device according to claim 27, wherein a concentration of P type dopants in the bottom P well epitaxial layer is more than 1×10¹⁷ (cm⁻³) and less than 5×10¹⁹ (cm^{'13}).

35. The semiconductor device according to claim 27, wherein the gate insulating layer comprises SiO₂, SiON, SiN or a high dielectric constant material.

36. The semiconductor device according to claim 35, wherein the high dielectric constant material comprises Al₂O₃, HfO₂ or ZrO₂.

37. The semiconductor device according to claim 27, wherein the gate comprises polycrystalline silicon (poly-Si), titanium (Ti), aluminum (Al), tungsten (W) or gold (Au).

38. The semiconductor device according to claim 27, wherein the gate is a general gate or a dummy gate.
